(19) United States
(12) Patent Application Publication
(10) Pub. No.: US 2025/0022779 A1
(43) Pub. Date: Jan. 16, 2025

(54) SEMICONDUCTOR PACKAGE

(71) Applicant: SAMSUNG ELECTRO-MECHANICS CO., LTD., Suwon-si (KR)

(72) Inventors: Sijoong YANG, Suwon-si (KR); Joon Seok CHAE, Suwon-si (KR); Dongsoon WOO, Suwon-si (KR); Daeyoung CHOI, Suwon-si (KR); Taeseok KO, Suwon-si (KR)

(73) Assignee: SAMSUNG ELECTRO-MECHANICS CO., LTD., Suwon-si (KR)

(21) Appl. No.: 18/661,992

(22) Filed: May 13, 2024

(30) Foreign Application Priority Data
Jul. 13, 2023 (KR) 10-2023-0091200

(51) Int. Cl. H01L 23/495; H01L 23/00

(52) U.S. Cl. CPC H01L 23/49548; H01L 23/49537; H01L 23/49575; H01L 24/08; H01L 24/32; H01L 2224/08245; H01L 2224/32245; H01L 2924/1815

(57) ABSTRACT

A semiconductor package is provided. The semiconductor package includes a first lead frame and a second lead frame that face each other; and a semiconductor element that is disposed between the first lead frame and the second lead frame, wherein the semiconductor element is connected to the first lead frame through a first contacting portion, and is connected to the second lead frame through a second contacting portion. The second lead frame includes a hole that overlaps the second contacting portion.

### CROSS-REFERENCE TO RELATED APPLICATIONS

This application claims the benefit under 35 USC § 119 (a) of Korean Patent Application No. 10-2023-0091200 filed on Jul. 13, 2023, in the Korean Intellectual Property Office, the entire disclosure of which is incorporated herein by reference for all purposes.

### BACKGROUND

### 1. Field

The following description relates to a semiconductor package.

### 2. Description of Related Art

As semiconductor devices are developed, a highly integrated semiconductor package is being produced.

If heat is internally generated as a semiconductor element included in the semiconductor package operates and the internal heat is not dissipated to the outside, a temperature of the semiconductor element may increase and a failure rate of the element may increase.

Particularly, since a power semiconductor package may be driven using a high voltage and a high current, the heat generated when the element is driven increases. Performance of a power semiconductor element may be deteriorated and energy loss may occur, or an insulating layer inside the power semiconductor may be destroyed so that reliability is lowered due to the heat generated when the power semiconductor package is driven.

On the other hand, it is necessary to maintain thermal durability along with a physical strength of a support substrate that supports the semiconductor element within the semiconductor package, and at the same time, an effort is needed to prevent a complicated manufacturing process or a defect such as disconnection of a connection portion or the like.

The above information is presented as background information only to assist with an understanding of the present disclosure. No determination has been made, and no assertion is made, as to whether any of the above might be applicable as prior art with regard to the disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

A semiconductor package, including a first lead frame and a second lead frame that face each other; and a semiconductor element that is disposed between the first lead frame and the second lead frame, wherein the semiconductor element is connected to the first lead frame through a first contacting portion, and is connected to the second lead frame through a second contacting portion, and wherein the second lead frame includes a hole that overlaps the second contacting portion.

The second lead frame may include a plurality of protrusions that protrude toward the semiconductor element.

A cross-section of each of the plurality of protrusions cut in a direction parallel to a height direction may have a semicircular shape.

The second lead frame may further include a first portion and a second portion that are spaced apart from each other, and the plurality of protrusions comprise a first protrusion included in the first portion and a second protrusion included in the second portion.

A width of the first protrusion may be substantially equal to a width of the second protrusion.

The hole may overlap the second protrusion.

Lower surfaces of the plurality of protrusions may be flat.

The second lead frame further may include a first portion and a second portion that are spaced apart from each other, and the hole may include a first hole that overlaps a protrusion of the first portion and a second hole that overlaps a protrusion of the second portion.

A width of the protrusion of the first portion may be substantially equal to a width of the protrusion of the second portion.

A width of the first hole may be substantially equal to a width of the second hole.

A width of the protrusion of the first portion may be different from a width of the protrusion of the second portion.

A width of the first hole may be different from a width of the second hole.

The first lead frame may include a first frame portion on which the semiconductor element is mounted, a second frame portion that is spaced apart from the first frame portion, is configured to receive a first signal from an external source, and is disposed in a nonoverlapping manner with regard to the semiconductor element, and a third frame portion that is spaced apart from the second frame portion, and is disposed in a nonoverlapping manner with regard to the semiconductor element, wherein the semiconductor package further includes a third contacting portion disposed between the second lead frame and the semiconductor element, a fourth contacting portion disposed between the second frame portion and the second lead frame and configured to have conductivity, and a spacer disposed between the third frame portion and the second lead frame.

A thickness of the fourth contacting portion may be substantially equal to a thickness of the spacer.

In a general aspect semiconductor package includes a first lead frame including a first frame portion on which a semiconductor element is mounted, a second frame portion that is spaced apart from the first frame portion, is configured to receive a first signal from an external source, and is disposed in a nonoverlapping manner with regard to the semiconductor element, and a third frame portion that is spaced apart from the second frame portion and is disposed in a nonoverlapping manner with regard to the semiconductor element; a second lead frame that faces the first lead frame; a contacting portion that is disposed between the second frame portion and the second lead frame and is configured to have conductivity; and a spacer disposed between the third frame portion and the second lead frame.

A thickness of the contacting portion may be substantially equal to a thickness of the spacer.

The second lead frame includes a plurality of protrusions that protrude toward the semiconductor element.

A cross-section of each of the plurality of protrusions cut in a direction parallel to a height direction may have a semicircular shape.

Lower surfaces of the plurality of protrusions may be flat.

The second lead frame may include a first portion and a second portion spaced apart from each other, the plurality of protrusions may include a first protrusion included in the first portion and a second protrusion included in the second portion, and a width of the first protrusion of the first portion is different from a width of the second protrusion of the second portion.

Other features and aspects will be apparent from the following detailed description, the drawings, and the claims.

### BRIEF DESCRIPTION OF DRAWINGS

FIG. 1 illustrates an exploded perspective view of an example semiconductor package, in accordance with one or more embodiments.

FIG. 2 illustrates a cross-sectional view cut along a line I-I′ of FIG. 1.

FIG. 3 illustrates a cross-sectional view of an example semiconductor package, in accordance with one or more embodiments.

FIG. 4 illustrates a cross-sectional view of an example semiconductor package, in accordance with one or more embodiments.

FIG. 5 illustrates a cross-sectional view of an example semiconductor package, in accordance with one or more embodiments.

FIG. 6 illustrates a cross-sectional view of an example semiconductor package, in accordance with one or more embodiments.

FIG. 7 illustrates a cross-sectional view of an example semiconductor package, in accordance with one or more embodiments.

FIG. 8 illustrates a cross-sectional view of an example semiconductor package, in accordance with one or more embodiments.

FIG. 9 illustrates a cross-sectional view of an example semiconductor package, in accordance with one or more embodiments.

Throughout the drawings and the detailed description, unless otherwise described, the same reference numerals refer to the same elements. The drawings may not be to scale, and the relative size, proportions, and depiction of elements in the drawings may be exaggerated for clarity, illustration, and convenience.

### DETAILED DESCRIPTION

Hereinafter, while examples of the present disclosure will be described in detail with reference to the accompanying drawings, it is noted that examples are not limited to the same.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of this disclosure. For example, the sequences of operations described herein are merely examples, and are not limited to those set forth herein, but may be changed as will be apparent after an understanding of this disclosure, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of this disclosure.

Throughout the specification, when an element, such as a layer, region, or substrate is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items; likewise, “at least one of” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms, such as “above,” “upper,” “below,” “lower,” and the like, may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above,” or “upper” relative to another element would then be “below,” or “lower” relative to the other element. Thus, the term “above” encompasses both the above and below orientations depending on the spatial orientation of the device. The device may also be oriented in other ways (rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

Herein, it is noted that use of the term “may” with respect to an example, for example, as to what an example may include or implement, means that at least one example exists in which such a feature is included or implemented while all examples are not limited thereto.

The features of the examples described herein may be combined in various ways as will be apparent after an understanding of this disclosure. Further, although the examples described herein have a variety of configurations, other configurations are possible as will be apparent after an understanding of this disclosure.

Throughout the one or more examples, a pattern, a via, a plane, a line, and an electrical connection structure may include a metallic material (e.g., a conductive material such as copper (Cu), aluminum (Al), silver (Ag), tin (Sn), gold (Au), nickel (Ni), lead (Pb), titanium (Ti), an alloy thereof, or the like), and may be formed according to a plating method such as chemical vapor deposition (CVD), physical vapor deposition (PVD), sputtering, a subtractive process, an additive process, a semi-additive process (SAP), a modified semi-additive process (MSAP), or the like, but this is not restrictive.

Throughout the one or more examples, a dielectric layer and/or an insulating layer may be implemented with a thermosetting resin such as FR4, a liquid crystal polymer (LCP), a lower temperature co-fired ceramic (LTCC), or an epoxy resin, a thermoplastic resin such as polyimide, a resin formed by impregnating the thermosetting resin and the thermoplastic resin in a core material such as a glass fiber (or a glass cloth or a glass fabric) with an inorganic filler, a prepreg, an Ajinomoto build-up film (ABF), FR-4, bismaleimide triazine (BT), a photoimageable dielectric (PID) resin, a typical copper clad laminate (CCL), a glass, a ceramic-based insulating material, or the like.

Throughout the one or more examples, a radio frequency (RF) signal may have a format according to other random wireless and wired protocols designated by, as only examples, Wi-Fi (IEEE 802.11 family, etc.), WiMAX (IEEE 802.16 family, etc.), IEEE 802.20, long term evolution (LTE), Evolution-Data Optimized (Ev-DO), high-speed packet access plus (HSPA+), high-speed downlink packet access plus (HSDPA+), high-speed uplink packet access plus (HSUPA+), Enhanced Data GSM Evolution (EDGE), Global System for Mobile communication (GSM), Global Positioning System (GPS), General Packet Radio Service (GPRS), Code Division Multiple Access (CDMA), Time Division Multiple Access (TDMA), digital enhanced cordless communication (DECT), Bluetooth, third generation (3G), fourth generation (4G), fifth generation (5G), and any other wireless and wired protocols designated thereafter, but is not limited thereto.

One or more examples may provide a semiconductor package that enables heat dissipation inside the semiconductor package, and does not complicate a manufacturing process.

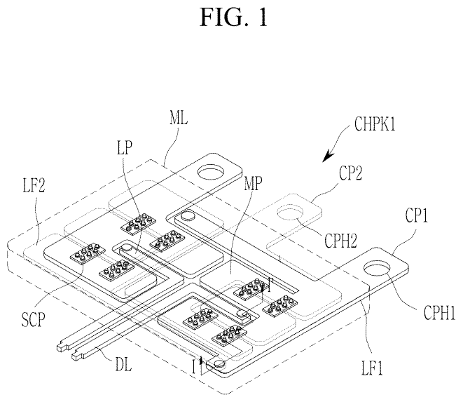

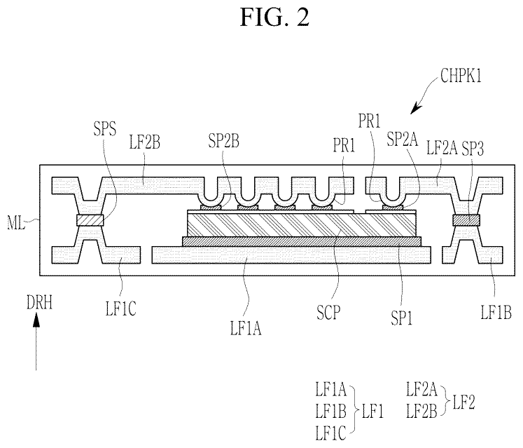

With reference to FIGS. 1 and 2, an example semiconductor package CHPK1, in accordance with one or more embodiments, will be described. FIG. 1 is an exploded perspective view of the example semiconductor package, in accordance with one or more embodiments, and FIG. 2 is a cross-sectional view cut along a line I-I′ of FIG. 1.

Referring to FIG. 1 and FIG. 2, the example semiconductor package CHPK1, in accordance with one or more embodiments, may include a first lead frame LF1 and a second lead frame LF2 which face each other, a plurality of semiconductor elements SCP disposed between the first lead frame LF1 and the second lead frame LF2, and a molding portion ML that seals the plurality of semiconductor elements SCP.

Referring to FIG. 1, the first lead frame LF1 may include a mounting portion MP on which the plurality of semiconductor elements SCP are mounted, a wiring portion LP spaced apart from mounting portion MP, a lead-out portion DL that extends from the wiring portion LP to the outside and receives a signal from the outside, a first connecting portion CP1 extending outwards from the mounting portion MP to be assembled and connected to a semiconductor device, and a first connecting hole CPH1 formed at the first connecting portion CP1.

The second lead frame LF2 may include a mounting portion MP where the plurality of semiconductor elements SCP are mounted, a second connecting portion CP2 extending outwards from the mounting portion MP to be assembled and connected to a semiconductor device, and a second connecting hole CPH2 formed at the second connecting portion CP2.

The first lead frame LF1 and the second lead frame LF2 may include a metal, and may be made of a single layer. In an example, the first lead frame LF1 and the second lead frame LF2 may include at least one of copper (Cu), nickel (Ni), and iron (Fe). However, the embodiment is not limited thereto.

Referring to FIG. 2, the first lead frame LF1 may include a first frame portion LF1A, a second frame portion LF1B, and a third frame portion LF1C, and the second lead frame LF2 may include a fourth frame portion LF2A and a fifth frame portion LF2B.

The semiconductor element SCP may be mounted on the first frame portion LF1A of the first lead frame LF1. The semiconductor element SCP may be physically and electrically connected to the first lead frame LF1 through a first contacting portion SP1. The first frame portion LF1A of the first lead frame LF1 may be the mounting portion MP of FIG. 1, but the embodiment is not limited thereto.

A first signal may be applied from the outside to the second frame portion LF1B of the first lead frame LF1 through the lead-out portion DL, and the second frame portion LF1B of the first lead frame LF1 may be the wiring portion LP of FIG. 1. However, the embodiment is not limited thereto. The second frame portion LF1B of the first lead frame LF1 may not overlap the semiconductor element SCP along a height direction DRH.

An electrical signal may not be applied to the third frame portion LF1C of the first lead frame LF1. However, the embodiment is not limited thereto. The third frame portion LF1C of the first lead frame LF1 may not overlap the semiconductor element SCP along the height direction DRH.

The semiconductor element SCP may be physically and electrically connected to the fourth frame portion LF2A and the fifth frame portion LF2B of the second lead frame LF2 through a second contacting portion SP2A and a third contacting portion SP2B.

The second frame portion LF1B of the first lead frame LF1 may be physically and electrically connected to the fourth frame portion LF2A of the second lead frame LF2 through a fourth contacting portion SP3, so that the first signal applied to the second frame portion LF1B of the first lead frame LF1 through the lead-out portion DL is applied to the semiconductor element SCP through the fourth contacting portion SP3, the fourth frame portion LF2A of the second lead frame LF2, and the second contacting portion SP2A. In an example, the semiconductor element SCP may be an electric power semiconductor element, the semiconductor element SCP may receive a first signal applied to the first frame portion LF1A of the first lead frame LF1 through the fourth contacting portion SP3, and the first signal may be a power signal.

A second signal may be applied to the fifth frame portion LF2B of the second lead frame LF2, and the second signal applied to the fifth frame portion LF2B of the second lead frame LF2 may be applied to the semiconductor element SCP through the third contacting portion SP2B.

Each of the first contacting portion SP1, the second contacting portion SP2A, the third contacting portion SP2B, and the fourth contacting portion SP3 may include a solder paste, but the embodiment is not limited thereto.

A spacer SPS may be disposed between the third frame portion LF1C of the first lead frame LF1 and the fifth frame portion LF2B of the second lead frame LF2.

A thickness of the spacer SPS may be almost the same as a thickness of the fourth contacting portion SP3 that connects the second frame portion LF1B of the first lead frame LF1 and the fourth frame portion LF2A of the second lead frame LF2.

In an example, the spacer SPS may include an insulating material.

Therefore, an interval between the third frame portion LF1C of the first lead frame LF1 and the fifth frame portion LF2B of the second lead frame LF2 through the spacer SPS may be almost the same as an interval between the second frame portion LF1B of the first lead frame LF1 and the fourth frame portion LF2A of the second lead frame LF2. Accordingly, a height of the fifth frame portion LF2B of the second lead frame LF2 where the fourth contacting portion SP3 is not disposed may be prevented from being relatively lowered so that warpage of the second lead frame LF2 is prevented.

Surfaces of the fourth frame portion LF2A and the fifth frame portion LF2B of the second lead frame LF2 that are physically and electrically connected to the semiconductor element SCP through the second contacting portion SP2A and the third contacting portion SP2B may include a plurality of first protrusions PR1 protruding toward the semiconductor element SCP along the height direction DRH.

The second contacting portion SP2A and the third contacting portion SP2B may contact the plurality of first protrusions PR1 of the surfaces of the fourth frame portion LF2A and the fifth frame portion LF2B.

A cross-section cut along a direction parallel to the height direction DRH of the plurality of first protrusions PR1 of the surfaces of the fourth frame portion LF2A and the fifth frame portion LF2B may have a semicircular shape, but the embodiment is not limited thereto.

A width of the first protrusion PR1 of the fourth frame portion LF2A and a width of the first protrusion PR1 of the fifth frame portion LF2B may be almost the same.

The surfaces of the fourth frame portion LF2A and the fifth frame portion LF2B of the second lead frame LF2 that are physically and electrically connected to the semiconductor element SCP may include the plurality of first protrusions PR1 so that bonding reliability is improved by increasing a bonding surface area between the semiconductor element SCP and the second lead frame LF2. An interval between the semiconductor element SCP and the second lead frame LF2 may be maintained so that heat generated in the semiconductor element SCP is easily transferred to the outside.

The molding portion ML may surround and seal the first lead frame LF1, the second lead frame LF2, and the semiconductor element SCP.

The molding portion ML may protect the first lead frame LF1, the second lead frame LF2, and the semiconductor element SCP that are included therein.

As shown in FIG. 1, the lead-out portion DL, the first connecting portion CP1, and the first connecting hole CPH1 of the first lead frame LF1 and the second connecting portion CP2 and the second connecting hole CPH2 of the second lead frame LF2 may be exposed to the outside of the molding portion ML.

In an example, the molding portion ML may include a polymer with excellent insulating and protective properties, and in an example, the molding portion ML may include an epoxy molding compound (EMC) or a polyimide-based material, as only examples.

According to the semiconductor package CHPK1 according to the embodiment, the plurality of semiconductor elements SCP may be mounted on the first lead frame LF1 and the second lead frame LF2 without a complicated process of forming a separate mounting substrate, so that a manufacturing process may be simple and an increase in a manufacturing cost may be prevented.

According to the semiconductor package CHPK1 according to the embodiment, the first lead frame LF1 and the second lead frame LF2 may be respectively disposed below and above the semiconductor element SCP along the height direction DRH, so that heat may be transferred above and below the semiconductor element SCP. A surface of the second lead frame LF2 connected to the semiconductor element SCP may include the plurality of first protrusions PR1 so that bonding reliability is improved by increasing a bonding surface area between the semiconductor element SCP and the second lead frame LF2. An interval between the semiconductor element SCP and the second lead frame LF2 may be maintained so that heat generated in the semiconductor element SCP is easily transferred to the outside.

According to the semiconductor package CHPK1 according to the embodiment, an interval between the third frame portion LF1C of the first lead frame LF1 and the fifth frame portion LF2B of the second lead frame LF2 through the spacer SPS may be almost the same as an interval between the second frame portion LF1B of the first lead frame LF1 and the fourth frame portion LF2A of the second lead frame LF2. Accordingly, a height of the fifth frame portion LF2B of the second lead frame LF2 where the fourth contacting portion SP3 is not disposed may be prevented from being relatively lowered so that warpage of the second lead frame LF2 is prevented.

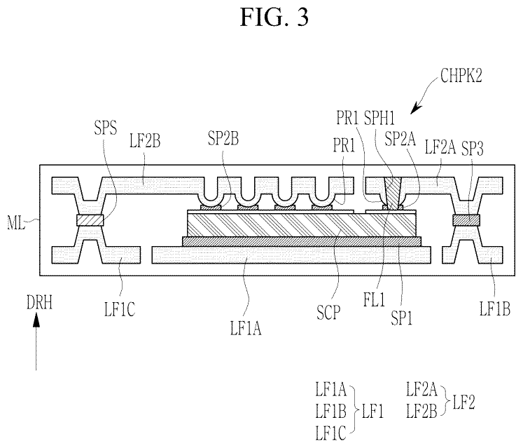

With reference to FIG. 3, an example semiconductor package CHPK2, in accordance with one or more embodiments, will be described. FIG. 3 is a cross-sectional view of the semiconductor package, in accordance with one or more embodiments.

Referring to FIG. 3, the semiconductor package CHPK2, in accordance with one or more embodiments, is similar to the semiconductor package CHPK1 according to the embodiments previously described with reference to FIGS. 1 and 2. A detailed description of the same constituent element is omitted.

The semiconductor package CHPK2, in accordance with one or more embodiments, may include the first lead frame LF1 and the second lead frame LF2 facing each other, the plurality of semiconductor elements SCP disposed between the first lead frame LF1 and the second lead frame LF2, and the molding portion ML that seals the plurality of semiconductor elements SCP.

The first lead frame LF1 may include the first frame portion LF1A, the second frame portion LF1B, and the third frame portion LF1C, and the second lead frame LF2 may include the fourth frame portion LF2A and the fifth frame portion LF2B.

The semiconductor element SCP may be mounted on the first frame portion LF1A of the first lead frame LF1. The semiconductor element SCP may be physically and electrically connected to the first lead frame LF1 through the first contacting portion SP1.

The fourth frame portion LF2A and the fifth frame portion LF2B of the second lead frame LF2 may be physically and electrically connected to the semiconductor element SCP through the second contacting portion SP2A and the third contacting portion SP2B.

The second frame portion LF1B of the first lead frame LF1 may be physically and electrically connected to the second lead frame LF2 through the fourth contacting portion SP3.

The spacer SPS may be disposed between the third frame portion LF1C of the first lead frame LF1 and the fifth frame portion LF2B of the second lead frame LF2.

In an example, a thickness of the spacer SPS may be almost the same as a thickness of the fourth contacting portion SP3 that connects the second frame portion LF1B of the first lead frame LF1 and the fourth frame portion LF2A of the second lead frame LF2.

Surfaces of the fourth frame portion LF2A and the fifth frame portion LF2B of the second lead frame LF2 that are physically and electrically connected to the semiconductor element SCP through the second contacting portion SP2A and the third contacting portion SP2B may include the plurality of first protrusions PR1 protruding toward the semiconductor element SCP along the height direction DRH.

The second contacting portion SP2A and the third contacting portion SP2B may contact the plurality of first protrusions PR1 of the surfaces of the fourth frame portion LF2A and the fifth frame portion LF2B.

The plurality of first protrusions PR1 of the surfaces of the fourth frame portion LF2A and the fifth frame portion LF2B may have a hemisphere shape, but the embodiment is not limited thereto.

A width of the first protrusion PR1 of the fourth frame portion LF2A and a width of the first protrusion PR1 of the fifth frame portion LF2B may be almost the same.

The molding portion ML may surround and seal the first lead frame LF1, the second lead frame LF2, and the semiconductor element SCP.

The molding portion ML may protect the first lead frame LF1, the second lead frame LF2, and the semiconductor element SCP that are included therein.

Unlike the semiconductor package CHPK1 according to the embodiment described above, at least one of the plurality of first protrusions PR1 of the second lead frame LF2 may include a first align hole (or a first alignment hole) SPH1 in the semiconductor package CHPK2 according to the present embodiment. For example, the first protrusion PR1 of the fourth frame portion LF2A of the second lead frame LF2 may include the first align hole SPH1, and a first filling layer FL1 may be disposed in the first align hole SPH1.

Alignment accuracy of the semiconductor element SCP and the second lead frame LF2 overlapping each other along the height direction DRH may be increased through the first align hole SPH1 formed at the first protrusion PR1 of the second lead frame LF2, so that misalignment is reduced.

The first align hole SPH1 of the second lead frame LF2 may be formed through any one method of punching, drilling, and etching, as only examples. The first filling layer FL1 may include a conductive material, but the embodiment is not limited thereto. The first filling layer FL1 may include the conductive material so that deterioration of a connection characteristic between the first protrusion PR1 of the second lead frame LF2 and the semiconductor element SCP is prevented.

According to the semiconductor package CHPK2 according to the embodiment, the plurality of semiconductor elements SCP may be mounted on the first lead frame LF1 and the second lead frame LF2 without a complicated process of forming a separate mounting substrate, so that a manufacturing process may be simple and an increase in a manufacturing cost may be prevented.

According to the semiconductor package CHPK2 according to the embodiment, the first lead frame LF1 and the second lead frame LF2 may be respectively disposed below and above the semiconductor element SCP along the height direction DRH, so that heat may be transferred above and below the semiconductor element SCP. A surface of the second lead frame LF2 connected to the semiconductor element SCP may include the plurality of first protrusions PR1 so that bonding reliability is improved by increasing a bonding surface area between the semiconductor element SCP and the second lead frame LF2. An interval between the semiconductor element SCP and the second lead frame LF2 may be maintained so that heat generated in the semiconductor element SCP is easily transferred to the outside.

According to the semiconductor package CHPK2 according to the embodiment, an interval between the third frame portion LF1C of the first lead frame LF1 and the fifth frame portion LF2B of the second lead frame LF2 through the spacer SPS may be almost the same as an interval between the second frame portion LF1B of the first lead frame LF1 and the fourth frame portion LF2A of the second lead frame LF2. Accordingly, a height of the fifth frame portion LF2B of the second lead frame LF2 where the fourth contacting portion SP3 is not disposed may be prevented from being relatively lowered so that warpage of the second lead frame LF2 is prevented.

According to the semiconductor package CHPK2 according to the embodiment, alignment accuracy of the semiconductor element SCP and the second lead frame LF2 overlapping each other along the height direction DRH may be increased through the first align hole SPH1 formed at the first protrusion PR1 of the second lead frame LF2, so that misalignment is reduced.

Many features of the example semiconductor package CHPK1 according to the embodiment described above are all applicable to the example semiconductor package CHPK2 according to the present embodiment.

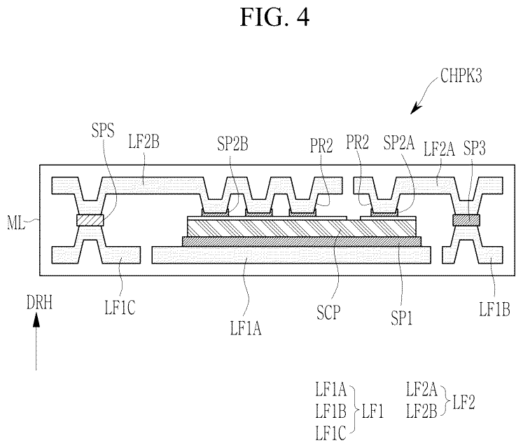

With reference to FIG. 4, an example semiconductor package CHPK3, in accordance with one or more embodiments, will be described. FIG. 4 is a cross-sectional view of the example semiconductor package, in accordance with one or more embodiments.

Referring to FIG. 4, the example semiconductor package CHPK3, in accordance with one or more embodiments, is similar to the example semiconductor packages CHPK1 and CHPK2 according to the embodiments described above. A detailed description of the same constituent element is omitted.

The example semiconductor package CHPK3 according to the present embodiment may include the first lead frame LF1 and the second lead frame LF2 facing each other, the plurality of semiconductor elements SCP disposed between the first lead frame LF1 and the second lead frame LF2, and the molding portion ML that seals the plurality of semiconductor elements SCP.

The first lead frame LF1 may include the first frame portion LF1A, the second frame portion LF1B, and the third frame portion LF1C, and the second lead frame LF2 may include the fourth frame portion LF2A and the fifth frame portion LF2B spaced apart from each other.

The semiconductor element SCP may be mounted on the first frame portion LF1A of the first lead frame LF1. The semiconductor element SCP may be physically and electrically connected to the first lead frame LF1 through the first contacting portion SP1.

The fourth frame portion LF2A and the fifth frame portion LF2B of the second lead frame LF2 may be physically and electrically connected to the semiconductor element SCP through the second contacting portion SP2A and the third contacting portion SP2B.

The second frame portion LF1B of the first lead frame LF1 may be physically and electrically connected to the second lead frame LF2 through the fourth contacting portion SP3.

The spacer SPS may be disposed between the third frame portion LF1C of the first lead frame LF1 and the fifth frame portion LF2B of the second lead frame LF2.

In an example, a thickness of the spacer SPS may be almost the same as a thickness of the fourth contacting portion SP3 that connects the second frame portion LF1B of the first lead frame LF1 and the fourth frame portion LF2A of the second lead frame LF2.

Surfaces of the fourth frame portion LF2A and the fifth frame portion LF2B of the second lead frame LF2 that are physically and electrically connected to the semiconductor element SCP through the second contacting portion SP2A and the third contacting portion SP2B may include a plurality of second protrusions PR2 that protrude toward the semiconductor element SCP along the height direction DRH.

The second contacting portion SP2A and the third contacting portion SP2B may contact the plurality of second protrusions PR2 of the surfaces of the fourth frame portion LF2A and the fifth frame portion LF2B.

Unlike the first protrusion PR1 of the example semiconductor packages CHPK1 and CHPK2 according to the embodiments described above, the plurality of second protrusions PR2 of a surface of the second lead frame LF2 may have flat lower surfaces that face the semiconductor element SCP in the semiconductor package CHPK3 according to the present embodiment.

In a non-limited example, a width of the second protrusion PR2 of the fourth frame portion LF2A and a width of the second protrusion PR2 of the fifth frame portion LF2B may be almost the same.

Since the lower surfaces of the plurality of second protrusions PR2 facing the semiconductor element SCP may be flat, a bonding surface area between the second lead frame LF2 and the semiconductor element SCP may be increased so that a bonding reliability between the second lead frame LF2 and the semiconductor element SCP is increased.

The molding portion ML may surround and seal the first lead frame LF1, the second lead frame LF2, and the semiconductor element SCP.

The molding portion ML may protect the first lead frame LF1, the second lead frame LF2, and the semiconductor element SCP that are included therein.

According to the example semiconductor package CHPK3 according to the embodiment, the plurality of semiconductor elements SCP may be mounted on the first lead frame LF1 and the second lead frame LF2 without a complicated process of forming a separate mounting substrate, so that a manufacturing process may be simple and an increase in a manufacturing cost may be prevented.

According to the example semiconductor package CHPK3 according to the embodiment, the first lead frame LF1 and the second lead frame LF2 may be respectively disposed below and above the semiconductor element SCP along the height direction DRH, so that heat may be transferred above and below the semiconductor element SCP. A surface of the second lead frame LF2 connected to the semiconductor element SCP may include the plurality of second protrusions PR2 so that bonding reliability is improved by increasing a bonding surface area between the semiconductor element SCP and the second lead frame LF2. An interval between the semiconductor element SCP and the second lead frame LF2 may be maintained so that heat generated in the semiconductor element SCP is easily transferred to the outside.

According to the example semiconductor package CHPK3 according to the embodiment, an interval between the third frame portion LF1C of the first lead frame LF1 and the fifth frame portion LF2B of the second lead frame LF2 through the spacer SPS may be almost the same as an interval between the second frame portion LF1B of the first lead frame LF1 and the fourth frame portion LF2A of the second lead frame LF2. Accordingly, a height of the fifth frame portion LF2B of the second lead frame LF2 where the fourth contacting portion SP3 is not disposed may be prevented from being relatively lowered so that warpage of the second lead frame LF2 is prevented.

Many features of the example semiconductor packages CHPK1 and CHPK2 according to the embodiments described above are all applicable to the example semiconductor package CHPK3 according to the present embodiment.

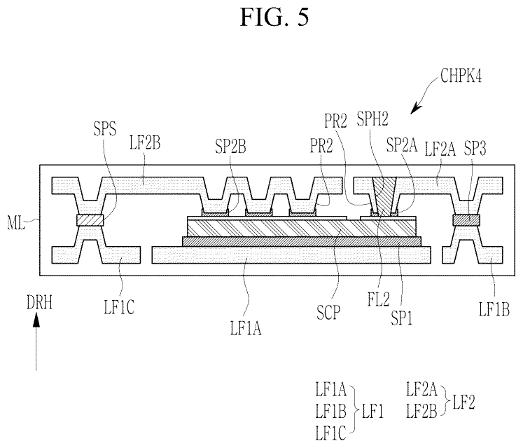

With reference to FIG. 5, an example semiconductor package CHPK4, in accordance with one or more embodiments, will be described. FIG. 5 is a cross-sectional view of the example semiconductor package, in accordance with one or more embodiments.

Referring to FIG. 5, the example semiconductor package CHPK4, in accordance with one or more embodiments, is similar to the example semiconductor package CHPK3 according to the embodiment previously described with reference to FIG. 4. A detailed description of the same constituent element is omitted.

The example semiconductor package CHPK4 according to the present embodiment may include the first lead frame LF1 and the second lead frame LF2 that face each other, the plurality of semiconductor elements SCP disposed between the first lead frame LF1 and the second lead frame LF2, and the molding portion ML that seals the plurality of semiconductor elements SCP.

The first lead frame LF1 may include the first frame portion LF1A, the second frame portion LF1B, and the third frame portion LF1C, and the second lead frame LF2 may include the fourth frame portion LF2A and the fifth frame portion LF2B.

The semiconductor element SCP may be mounted on the first frame portion LF1A of the first lead frame LF1. The semiconductor element SCP may be physically and electrically connected to the first lead frame LF1 through the first contacting portion SP1.

The fourth frame portion LF2A and the fifth frame portion LF2B of the second lead frame LF2 may be physically and electrically connected to the semiconductor element SCP through the second contacting portion SP2A and the third contacting portion SP2B.

The second frame portion LF1B of the first lead frame LF1 may be physically and electrically connected to the second lead frame LF2 through the fourth contacting portion SP3.

The spacer SPS may be disposed between the third frame portion LF1C of the first lead frame LF1 and the fifth frame portion LF2B of the second lead frame LF2.

In an example, a thickness of the spacer SPS may be almost the same as a thickness of the fourth contacting portion SP3 that connects the second frame portion LF1B of the first lead frame LF1 and the fourth frame portion LF2A of the second lead frame LF2.

Surfaces of the fourth frame portion LF2A and the fifth frame portion LF2B of the second lead frame LF2 that are physically and electrically connected to the semiconductor element SCP through the second contacting portion SP2A and the third contacting portion SP2B may include the plurality of second protrusions PR2 that protrude toward the semiconductor element SCP along the height direction DRH.

The second contacting portion SP2A and the third contacting portion SP2B may contact the plurality of second protrusions PR2 of the surfaces of the fourth frame portion LF2A and the fifth frame portion LF2B.

Unlike the first protrusion PR1, the plurality of second protrusions PR2 of a surface of the second lead frame LF2 may have flat lower surfaces that face the semiconductor element SCP.

In an example, a width of the second protrusion PR2 of the fourth frame portion LF2A and a width of the second protrusion PR2 of the fifth frame portion LF2B may be almost the same.

Since the lower surfaces of the plurality of second protrusions PR2 facing the semiconductor element SCP may be flat, a bonding surface area between the second lead frame LF2 and the semiconductor element SCP may be increased so that a bonding reliability between the second lead frame LF2 and the semiconductor element SCP is increased.

The molding portion ML may surround and seal the first lead frame LF1, the second lead frame LF2, and the semiconductor element SCP.

The molding portion ML may protect the first lead frame LF1, the second lead frame LF2, and the semiconductor element SCP that are included therein.

Unlike the example semiconductor package CHPK3 according to the embodiment described above, at least one of the plurality of second protrusions PR2 of the second lead frame LF2 may include a second align hole (or a second alignment hole) SPH2 in the semiconductor package CHPK4 according to the present embodiment. In an example, the second protrusion PR2 of the fourth frame portion LF2A of the second lead frame LF2 may include the second align hole SPH2, and a second filling layer FL2 may be disposed in the second align hole SPH2.

Alignment accuracy of the semiconductor element SCP and the second lead frame LF2 overlapping each other along the height direction DRH may be increased through the second align hole SPH2 formed at the second protrusion PR2 of the second lead frame LF2, so that misalignment is reduced.

The second align hole SPH2 of the second lead frame LF2 may be formed through any one method of punching, drilling, and etching, as only examples. The second filling layer FL2 may include a conductive material. However, the embodiments are not limited thereto. The second filling layer FL2 may include the conductive material so that deterioration of a connection characteristic between the second protrusion PR2 of the second lead frame LF2 and the semiconductor element SCP is prevented.

According to the example semiconductor package CHPK4 according to the embodiment, the plurality of semiconductor elements SCP may be mounted on the first lead frame LF1 and the second lead frame LF2 without a complicated process of forming a separate mounting substrate, so that a manufacturing process may be simple and an increase in a manufacturing cost may be prevented.

According to the example semiconductor package CHPK4 according to the embodiment, the first lead frame LF1 and the second lead frame LF2 may be respectively disposed below and above the semiconductor element SCP along the height direction DRH, so that heat may be transferred above and below the semiconductor element SCP. A surface of the second lead frame LF2 connected to the semiconductor element SCP may include the plurality of second protrusions PR2 so that bonding reliability is improved by increasing a bonding surface area between the semiconductor element SCP and the second lead frame LF2. An interval between the semiconductor element SCP and the second lead frame LF2 may be maintained so that heat generated in the semiconductor element SCP may be easily transferred to the outside.

According to the example semiconductor package CHPK4 according to the embodiment, an interval between the third frame portion LF1C of the first lead frame LF1 and the fifth frame portion LF2B of the second lead frame LF2 through the spacer SPS may be almost the same as an interval between the second frame portion LF1B of the first lead frame LF1 and the fourth frame portion LF2A of the second lead frame LF2. Accordingly, a height of the fifth frame portion LF2B of the second lead frame LF2 where the fourth contacting portion SP3 is not disposed may be prevented from being relatively lowered so that warpage of the second lead frame LF2 is prevented.

According to the example semiconductor package CHPK4 according to the embodiment, alignment accuracy of the semiconductor element SCP and the second lead frame LF2 overlapping each other along the height direction DRH may be increased through the second align hole SPH2 formed at the second protrusion PR2 of the second lead frame LF2, so that misalignment is reduced.

Many features of the example semiconductor packages CHPK1, CHPK2, and CHPK3 according to the embodiments described above are all applicable to the example semiconductor package CHPK4 according to the present embodiment.

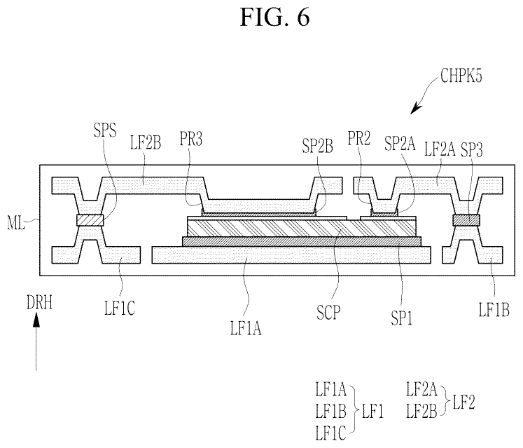

With reference to FIG. 6, an example semiconductor package CHPK5, in accordance with one or more embodiments, will be described. FIG. 6 is a cross-sectional view of the example semiconductor package, in accordance with one or more embodiments.

Referring to FIG. 6, the example semiconductor package CHPK5 according to the present embodiment is similar to the example semiconductor packages CHPK1, CHPK2, CHPK3, and CHPK4 according to the embodiments described above. A detailed description of the same constituent element is omitted.

The semiconductor package CHPK5 according to the present embodiment may include the first lead frame LF1 and the second lead frame LF2 that face each other, the plurality of semiconductor elements SCP disposed between the first lead frame LF1 and the second lead frame LF2, and the molding portion ML that seals the plurality of semiconductor elements SCP.

The first lead frame LF1 may include the first frame portion LF1A, the second frame portion LF1B, and the third frame portion LF1C, and the second lead frame LF2 may include the fourth frame portion LF2A and the fifth frame portion LF2B.

The semiconductor element SCP may be mounted on the first frame portion LF1A of the first lead frame LF1. The semiconductor element SCP may be physically and electrically connected to the first lead frame LF1 through the first contacting portion SP1.

The fourth frame portion LF2A and the fifth frame portion LF2B of the second lead frame LF2 may be physically and electrically connected to the semiconductor element SCP through the second contacting portion SP2A and the third contacting portion SP2B.

The second frame portion LF1B of the first lead frame LF1 may be physically and electrically connected to the second lead frame LF2 through the fourth contacting portion SP3.

The spacer SPS may be disposed between the third frame portion LF1C of the first lead frame LF1 and the fifth frame portion LF2B of the second lead frame LF2.

In an example, a thickness of the spacer SPS may be almost the same as a thickness of the fourth contacting portion SP3 that connects the second frame portion LF1B of the first lead frame LF1 and the fourth frame portion LF2A of the second lead frame LF2.

Unlike the semiconductor packages CHPK1, CHPK2, CHPK3, and CHPK4 according to the embodiments described above, in the semiconductor package CHPK5 according to the present embodiment, a surface of the fifth frame portion LF2B of the second lead frame LF2 that is physically and electrically connected to the semiconductor element SCP through the third contacting portion SP2B may include a third protrusion PR3 that protrudes toward the semiconductor element SCP along the height direction DRH, and a surface of the fourth frame portion LF2A of the second lead frame LF2 that is physically and electrically connected to the semiconductor element SCP through the second contacting portion SP2A may include the second protrusion PR2 that protrudes toward the semiconductor element SCP along the height direction DRH.

The second contacting portion SP2A and the third contacting portion SP2B may contact the second protrusion PR2 and the third protrusion PR3 of surfaces of the fourth frame portion LF2A and the fifth frame portion LF2B.

Unlike the first protrusion PR1, the third protrusion PR3 and the second protrusion PR2 of a surface of the second lead frame LF2 may have flat lower surfaces that face the semiconductor element SCP.

In an example, a width of the third protrusion PR3 may be larger than a width of the second protrusion PR2.

A planar area of a lower surface of the third protrusion PR3 may be larger than a planar area of a lower surface of the second protrusion PR2.

Since the lower surfaces of the third protrusion PR3 and the second protrusion PR2 facing the semiconductor element SCP may be flat, a bonding surface area between the second lead frame LF2 and the semiconductor element SCP may be increased so that a bonding reliability between the second lead frame LF2 and the semiconductor element SCP is increased.

The molding portion ML may surround and seal the first lead frame LF1, the second lead frame LF2, and the semiconductor element SCP.

The molding portion ML may protect the first lead frame LF1, the second lead frame LF2, and the semiconductor element SCP that are included therein.

According to the semiconductor package CHPK5 according to the embodiment, the plurality of semiconductor elements SCP may be mounted on the first lead frame LF1 and the second lead frame LF2 without a complicated process of forming a separate mounting substrate, so that a manufacturing process may be simple and an increase in a manufacturing cost may be prevented.

According to the semiconductor package CHPK5 according to the embodiment, the first lead frame LF1 and the second lead frame LF2 may be respectively disposed below and above the semiconductor element SCP along the height direction DRH, so that heat may be transferred above and below the semiconductor element SCP. A surface of the second lead frame LF2 connected to the semiconductor element SCP may include the third protrusion PR3 and the second protrusion PR2 so that bonding reliability is improved by increasing a bonding surface area between the semiconductor element SCP and the second lead frame LF2. An interval between the semiconductor element SCP and the second lead frame LF2 may be maintained so that heat generated in the semiconductor element SCP is easily transferred to the outside.

According to the semiconductor package CHPK5 according to the embodiment, an interval between the third frame portion LF1C of the first lead frame LF1 and the fifth frame portion LF2B of the second lead frame LF2 through the spacer SPS may be almost the same as an interval between the second frame portion LF1B of the first lead frame LF1 and the fourth frame portion LF2A of the second lead frame LF2. Accordingly, a height of the fifth frame portion LF2B of the second lead frame LF2 where the fourth contacting portion SP3 is not disposed may be prevented from being relatively lowered so that warpage of the second lead frame LF2 is prevented.

Many features of the semiconductor packages CHPK1, CHPK2, CHPK3, and CHPK4 according to the embodiments described above are all applicable to the semiconductor package CHPK5 according to the present embodiment.

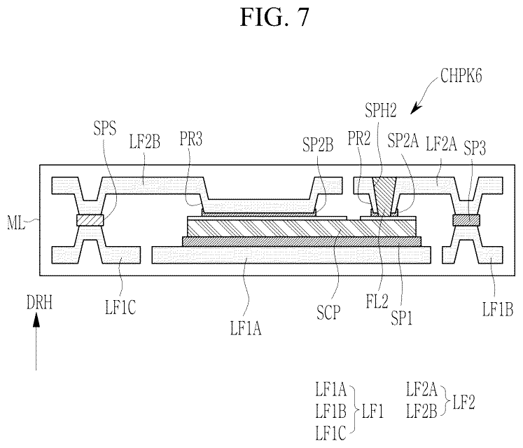

With reference to FIG. 7, an example semiconductor package CHPK6, in accordance with one or more embodiments, will be described. FIG. 7 is a cross-sectional view of the example semiconductor package, in accordance with one or more embodiments.

Referring to FIG. 7, the semiconductor package CHPK6 according to the present embodiment is similar to the semiconductor package CHPK5 according to the embodiment described above. A detailed description of the same constituent elements is omitted.

The semiconductor package CHPK6 according to the present embodiment may include the first lead frame LF1 and the second lead frame LF2 facing each other, the plurality of semiconductor elements SCP disposed between the first lead frame LF1 and the second lead frame LF2, and the molding portion ML that seals the plurality of semiconductor elements SCP.

The first lead frame LF1 may include the first frame portion LF1A, the second frame portion LF1B, and the third frame portion LF1C, and the second lead frame LF2 may include the fourth frame portion LF2A and the fifth frame portion LF2B.

The semiconductor element SCP may be mounted on the first frame portion LF1A of the first lead frame LF1. The semiconductor element SCP may be physically and electrically connected to the first lead frame LF1 through the first contacting portion SP1.

The fourth frame portion LF2A and the fifth frame portion LF2B of the second lead frame LF2 may be physically and electrically connected to the semiconductor element SCP through the second contacting portion SP2A and the third contacting portion SP2B.

The second frame portion LF1B of the first lead frame LF1 may be physically and electrically connected to the second lead frame LF2 through the fourth contacting portion SP3.

The spacer SPS may be disposed between the third frame portion LF1C of the first lead frame LF1 and the fifth frame portion LF2B of the second lead frame LF2.

In an example, a thickness of the spacer SPS may be almost the same as a thickness of the fourth contacting portion SP3 that connects the second frame portion LF1B of the first lead frame LF1 and the fourth frame portion LF2A of the second lead frame LF2.

A surface of the fourth frame portion LF2A of the second lead frame LF2 that is physically and electrically connected to the semiconductor element SCP through the second contacting portion SP2A may include the second protrusion PR2 that pretrudes toward the semiconductor element SCP along the height direction DRH, and a surface of the fifth frame portion LF2B of the second lead frame LF2 that is physically and electrically connected to the semiconductor element SCP through the third contacting portion SP2B may include the third protrusion PR3 protruding toward the semiconductor element SCP along the height direction DRH.

The second contacting portion SP2A and the third contacting portion SP2B may contact the second protrusion PR2 and the third protrusion PR3 of surfaces of the fourth frame portion LF2A and the fifth frame portion LF2B.

Unlike the first protrusion PR1, the third protrusion PR3 and the second protrusion PR2 of a surface of the second lead frame LF2 may have flat lower surfaces that face the semiconductor element SCP.

In an example, a width of the third protrusion PR3 may be larger than a width of the second protrusion PR2.

In an example, a planar area of a lower surface of the third protrusion PR3 may be larger than a planar area of a lower surface of the second protrusion PR2.

Because the lower surfaces of the third protrusion PR3 and the second protrusion PR2 facing the semiconductor element SCP are flat, a bonding surface area between the second lead frame LF2 and the semiconductor element SCP may be increased so that a bonding reliability between the second lead frame LF2 and the semiconductor element SCP is increased.

The molding portion ML may surround and seal the first lead frame LF1, the second lead frame LF2, and the semiconductor element SCP.

The molding portion ML may protect the first lead frame LF1, the second lead frame LF2, and the semiconductor element SCP that are included therein.

Unlike the semiconductor package CHPK5 according to the embodiment described above, at least one of the plurality of second protrusions PR2 of the second lead frame LF2 may include the second align hole (or the second alignment hole) SPH2 in the semiconductor package CHPK6 according to the present embodiment. For example, the second protrusion PR2 of the fourth frame portion LF2A of the second lead frame LF2 may include the second align hole SPH2, and the second filling layer FL2 may be disposed in the second align hole SPH2.

Alignment accuracy of the semiconductor element SCP and the second lead frame LF2 overlapping each other along the height direction DRH may be increased through the second align hole SPH2 formed at the second protrusion PR2 of the second lead frame LF2, so that misalignment is reduced.

The second align hole SPH2 of the second lead frame LF2 may be formed through any one method of punching, drilling, and etching, as only examples. The second filling layer FL2 may include a conductive material, but the embodiment is not limited thereto. The second filling layer FL2 may include the conductive material so that deterioration of a connection characteristic between the second protrusion PR2 of the second lead frame LF2 and the semiconductor element SCP is prevented.

According to the semiconductor package CHPK6 according to the embodiment, the plurality of semiconductor elements SCP may be mounted on the first lead frame LF1 and the second lead frame LF2 without a complicated process of forming a separate mounting substrate, so that a manufacturing process may be simple and an increase in a manufacturing cost may be prevented.

According to the semiconductor package CHPK6 according to the embodiment, the first lead frame LF1 and the second lead frame LF2 may be respectively disposed below and above the semiconductor element SCP along the height direction DRH, so that heat may be transferred above and below the semiconductor element SCP. A surface of the second lead frame LF2 connected to the semiconductor element SCP may include the third protrusion PR3 and the second protrusion PR2 so that a bonding reliability is improved by increasing a bonding surface area between the semiconductor element SCP and the second lead frame LF2. An interval between the semiconductor element SCP and the second lead frame LF2 may be maintained so that heat generated in the semiconductor element SCP is easily transferred to the outside.

According to the semiconductor package CHPK6 according to the embodiment, an interval between the third frame portion LF1C of the first lead frame LF1 and the fifth frame portion LF2B of the second lead frame LF2 through the spacer SPS may be almost the same as an interval between the second frame portion LF1B of the first lead frame LF1 and the fourth frame portion LF2A of the second lead frame LF2. Accordingly, a height of the fifth frame portion LF2B of the second lead frame LF2 where the fourth contacting portion SP3 is not disposed may be prevented from being relatively lowered so that warpage of the second lead frame LF2 is prevented.

According to the semiconductor package CHPK6 according to the embodiment, alignment accuracy of the semiconductor element SCP and the second lead frame LF2 overlapping each other along the height direction DRH may be increased through the second align hole SPH2 formed at the second protrusion PR2 of the second lead frame LF2, so that misalignment is reduced.

Many features of the example semiconductor packages CHPK1, CHPK2, CHPK3, CHPK4, and CHPK5 according to the embodiments described above are all applicable to the example semiconductor package CHPK6 according to the present embodiment.

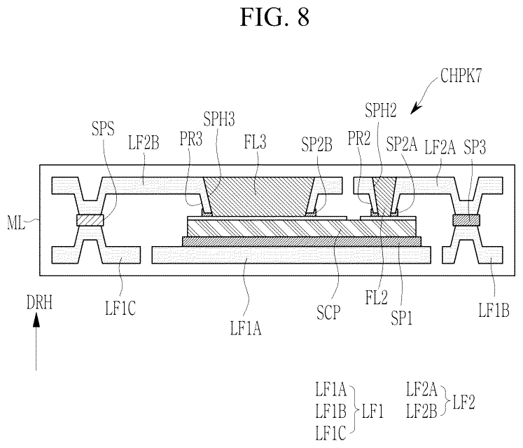

With reference to FIG. 8, an example semiconductor package CHPK7 according to another embodiment will be described. FIG. 8 is a cross-sectional view of the example semiconductor package, in accordance with one or more embodiments.

Referring to FIG. 8, the example semiconductor package CHPK7 according to the present embodiment is similar to the example semiconductor packages CHPK5 and CHPK6 according to the embodiments described above. A detailed description of the same constituent element is omitted.

The example semiconductor package CHPK7 according to the present embodiment may include the first lead frame LF1 and the second lead frame LF2 facing each other, the plurality of semiconductor elements SCP disposed between the first lead frame LF1 and the second lead frame LF2, and the molding portion ML that seals the plurality of semiconductor elements SCP.

The first lead frame LF1 may include the first frame portion LF1A, the second frame portion LF1B, and the third frame portion LF1C, and the second lead frame LF2 may include the fourth frame portion LF2A and the fifth frame portion LF2B.

The semiconductor element SCP may be mounted on the first frame portion LF1A of the first lead frame LF1. The semiconductor element SCP may be physically and electrically connected to the first lead frame LF1 through the first contacting portion SP1.

The fourth frame portion LF2A and the fifth frame portion LF2B of the second lead frame LF2 may be physically and electrically connected to the semiconductor element SCP through the second contacting portion SP2A and the third contacting portion SP2B.

The second frame portion LF1B of the first lead frame LF1 may be physically and electrically connected to the second lead frame LF2 through the fourth contacting portion SP3.

The spacer SPS may be disposed between the third frame portion LF1C of the first lead frame LF1 and the fifth frame portion LF2B of the second lead frame LF2.

In an example, a thickness of the spacer SPS may be almost the same as a thickness of the fourth contacting portion SP3 that connects the second frame portion LF1B of the first lead frame LF1 and the fourth frame portion LF2A of the second lead frame LF2.

A surface of the fourth frame portion LF2A of the second lead frame LF2 that is physically and electrically connected to the semiconductor element SCP through the second contacting portion SP2A may include the second protrusion PR2 that protrudes toward the semiconductor element SCP along the height direction DRH, and a surface of the fifth frame portion LF2B of the second lead frame LF2 that is physically and electrically connected to the semiconductor element SCP through the third contacting portion SP2B may include the third protrusion PR3 that protrudes toward the semiconductor element SCP along the height direction DRH.

The second contacting portion SP2A and the third contacting portion SP2B may contact the second protrusion PR2 and the third protrusion PR3 of surfaces of the fourth frame portion LF2A and the fifth frame portion LF2B.

Unlike the first protrusion PR1, the third protrusion PR3 and the second protrusion PR2 of a surface of the second lead frame LF2 may have flat lower surfaces that face the semiconductor element SCP.

In an example, a width of the third protrusion PR3 may be larger than a width of the second protrusion PR2.

In an example, a planar area of a lower surface of the third protrusion PR3 may be larger than a planar area of a lower surface of the second protrusion PR2.

Since the lower surfaces of the third protrusion PR3 and the second protrusion PR2 facing the semiconductor element SCP may be flat, a bonding surface area between the second lead frame LF2 and the semiconductor element SCP may be increased so that a bonding reliability between the second lead frame LF2 and the semiconductor element SCP is increased.

The molding portion ML may surround and seal the first lead frame LF1, the second lead frame LF2, and the semiconductor element SCP.

The molding portion ML may protect the first lead frame LF1, the second lead frame LF2, and the semiconductor element SCP that are included therein.

Unlike the example semiconductor package CHPK5 according to the embodiment described above, at least one of the plurality of second protrusions PR2 of the second lead frame LF2 may include the second align hole (or the second alignment hole) SPH2 in the semiconductor package CHPK7 according to the present embodiment. In an example, the second protrusion PR2 of the fourth frame portion LF2A of the second lead frame LF2 may include the second align hole SPH2, and the second filling layer FL2 may be disposed in the second align hole SPH2.

Additionally, at least one of third protrusions PR3 of the second lead frame LF2 may include a third align hole (or a third alignment hole) SPH3, and a third filling layer FL3 may be disposed in the third align hole SPH3. In an example, the third protrusion PR3 of the fifth frame portion LF2B of the second lead frame LF2 may include the third align hole SPH3, and the third filling layer FL3 may be disposed in the third align hole SPH3.

In an example, a width of the third align hole SPH3 of the second lead frame LF2 may be wider than a width of the second align hole SPH2 of the second lead frame LF2.

Alignment accuracy of the semiconductor element SCP and the second lead frame LF2 overlapping each other along the height direction DRH may be increased through the second align hole SPH2 formed at the second protrusion PR2 of the second lead frame LF2 and the third align hole SPH3 formed at the third protrusion PR3 of the second lead frame LF2, so that misalignment is reduced.

The second align hole SPH2 and the third align hole SPH3 of the second lead frame LF2 may be formed through any one method of punching, drilling, and etching, as only examples.

Each of the second filling layer FL2 and the third filling layer FL3 may include a conductive material, but the embodiment is not limited thereto. The second filling layer FL2 and the third filling layer FL3 may include the conductive material so that deterioration of a connection characteristic between the second protrusion PR2 and the third protrusion PR3 of the second lead frame LF2 and the semiconductor element SCP is prevented.

According to the semiconductor package CHPK7 according to the embodiment, the plurality of semiconductor elements SCP may be mounted on the first lead frame LF1 and the second lead frame LF2 without a complicated process of forming a separate mounting substrate, so that a manufacturing process may be simple and an increase in a manufacturing cost may be prevented.

According to the example semiconductor package CHPK7 according to the embodiment, the first lead frame LF1 and the second lead frame LF2 may be respectively disposed below and above the semiconductor element SCP along the height direction DRH, so that heat may be transferred above and below the semiconductor element SCP. A surface of the second lead frame LF2 connected to the semiconductor element SCP may include the third protrusion PR3 and the second protrusion PR2 so that bonding reliability is improved by increasing a bonding surface area between the semiconductor element SCP and the second lead frame LF2. An interval between the semiconductor element SCP and the second lead frame LF2 may be maintained so that heat generated in the semiconductor element SCP is easily transferred to the outside.

According to the example semiconductor package CHPK7 according to the embodiment, an interval between the third frame portion LF1C of the first lead frame LF1 and the fifth frame portion LF2B of the second lead frame LF2 through the spacer SPS may be almost the same as an interval between the second frame portion LF1B of the first lead frame LF1 and the fourth frame portion LF2A of the second lead frame LF2. Accordingly, a height of the fifth frame portion LF2B of the second lead frame LF2 where the fourth contacting portion SP3 is not disposed may be prevented from being relatively lowered so that warpage of the second lead frame LF2 is prevented.

According to the example semiconductor package CHPK7 according to the embodiment, alignment accuracy of the semiconductor element SCP and the second lead frame LF2 overlapping each other along the height direction DRH may be increased through the second align hole SPH2 and the third align hole SPH3 formed at the second protrusion PR2 and the third protrusion PR3 of the second lead frame LF2, so that misalignment is reduced.

Many features of the example semiconductor packages CHPK1, CHPK2, CHPK3, CHPK4, CHPK5, and CHPK6 according to the embodiments described above are all applicable to the example semiconductor package CHPK7 according to the present embodiment.

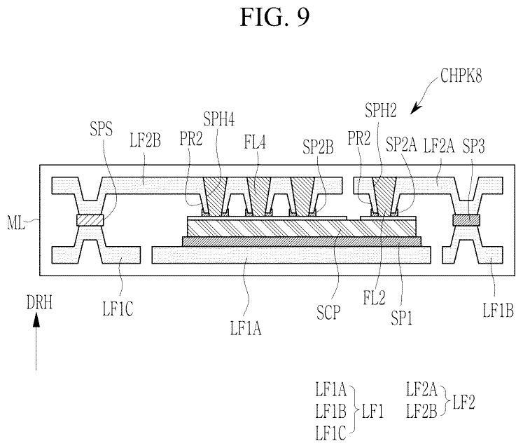

With reference to FIG. 9, an example semiconductor package CHPK8, in accordance with one or more embodiments, will be described. FIG. 9 is a cross-sectional view of the example semiconductor package, in accordance with one or more embodiments.

Referring to FIG. 9, the example semiconductor package CHPK8 according to the present embodiment is similar to the example semiconductor package CHPK4 according to the embodiment described above with reference to FIG. 5. A detailed description of the same constituent element is omitted.

The example semiconductor package CHPK8 according to the present embodiment may include the first lead frame LF1 and the second lead frame LF2 that face each other, the plurality of semiconductor elements SCP disposed between the first lead frame LF1 and the second lead frame LF2, and the molding portion ML that seals the plurality of semiconductor elements SCP.

The first lead frame LF1 may include the first frame portion LF1A, the second frame portion LF1B, and the third frame portion LF1C, and the second lead frame LF2 may include the fourth frame portion LF2A and the fifth frame portion LF2B.

The semiconductor element SCP may be mounted on the first frame portion LF1A of the first lead frame LF1. The semiconductor element SCP may be physically and electrically connected to the first lead frame LF1 through the first contacting portion SP1.

The fourth frame portion LF2A and the fifth frame portion LF2B of the second lead frame LF2 may be physically and electrically connected to the semiconductor element SCP through the second contacting portion SP2A and the third contacting portion SP2B.

The second frame portion LF1B of the first lead frame LF1 may be physically and electrically connected to the second lead frame LF2 through the fourth contacting portion SP3.

The spacer SPS may be disposed between the third frame portion LF1C of the first lead frame LF1 and the fifth frame portion LF2B of the second lead frame LF2.

In an example, a thickness of the spacer SPS may be almost the same as a thickness of the fourth contacting portion SP3 that connects the second frame portion LF1B of the first lead frame LF1 and the fourth frame portion LF2A of the second lead frame LF2.

Surfaces of the fourth frame portion LF2A and the fifth frame portion LF2B of the second lead frame LF2 that are physically and electrically connected to the semiconductor element SCP through the second contacting portion SP2A and the third contacting portion SP2B may include the plurality of second protrusions PR2 protruding toward the semiconductor element SCP along the height direction DRH.

The second contacting portion SP2A and the third contacting portion SP2B may contact the plurality of second protrusions PR2 of the surfaces of the fourth frame portion LF2A and the fifth frame portion LF2B.

Unlike the first protrusion PR1, the plurality of second protrusions PR2 of a surface of the second lead frame LF2 may have flat lower surfaces that face the semiconductor element SCP.

Since the lower surfaces of the plurality of second protrusions PR2 that face the semiconductor element SCP may be flat, a bonding surface area between the second lead frame LF2 and the semiconductor element SCP may be increased so that a bonding reliability between the second lead frame LF2 and the semiconductor element SCP is increased.

The molding portion ML may surround and seal the first lead frame LF1, the second lead frame LF2, and the semiconductor element SCP.

The molding portion ML may protect the first lead frame LF1, the second lead frame LF2, and the semiconductor element SCP that are included therein.

The second protrusion PR2 of the fourth frame portion LF2A of the second lead frame LF2 may include the second align hole SPH2, each of the plurality of second protrusions PR2 of the fifth frame portion LF2B of the second lead frame LF2 may include a fourth align hole (or a fourth alignment hole) SPH4, the second filling layer FL2 may be disposed in the second align hole SPH2, and a fourth filling layer FL4 may be disposed in the fourth align hole SPH4.

In an example, a width of the second protrusion PR2 of the fifth frame portion LF2B and widths of the plurality of second protrusions PR2 of the fourth frame portion LF2A may be almost the same, and a width of the second align hole SPH2 of the fifth frame portion LF2B and a width of the fourth align hole SPH4 of the fourth frame portion LF2A may be almost the same.

Alignment accuracy of the semiconductor element SCP and the second lead frame LF2 overlapping each other along the height direction DRH may be increased through the second align hole SPH2 and the fourth align hole SPH4 formed at the second protrusion PR2 of the second lead frame LF2, so that misalignment is reduced.

The second align hole SPH2 and the fourth align hole SPH4 of the second lead frame LF2 may be formed through any one method of punching, drilling, and etching, as only examples. Each of the second filling layer FL2 and the fourth filling layer FL4 may include a conductive material, but the embodiment is not limited thereto. The second filling layer FL2 and the fourth filling layer FL4 may include the conductive material so that deterioration of a connection characteristic between the second lead frame LF2 and the semiconductor element SCP is prevented.

According to the semiconductor package CHPK8 according to the embodiment, the plurality of semiconductor elements SCP may be mounted on the first lead frame LF1 and the second lead frame LF2 without a complicated process of forming a separate mounting substrate, so that a manufacturing process may be simple and an increase in a manufacturing cost may be prevented.

According to the semiconductor package CHPK8 according to the embodiment, the first lead frame LF1 and the second lead frame LF2 may be respectively disposed below and above the semiconductor element SCP along the height direction DRH, so that heat may be transferred above and below the semiconductor element SCP. A surface of the second lead frame LF2 connected to the semiconductor element SCP may include the plurality of second protrusions PR2 so that a bonding reliability is improved by increasing a bonding surface area between the semiconductor element SCP and the second lead frame LF2. An interval between the semiconductor element SCP and the second lead frame LF2 may be maintained so that heat generated in the semiconductor element SCP is easily transferred to the outside.

According to the semiconductor package CHPK8 according to the embodiment, an interval between the third frame portion LF1C of the first lead frame LF1 and the fifth frame portion LF2B of the second lead frame LF2 through the spacer SPS may be almost the same as an interval between the second frame portion LF1B of the first lead frame LF1 and the fourth frame portion LF2A of the second lead frame LF2. Accordingly, a height of the fifth frame portion LF2B of the second lead frame LF2 where the fourth contacting portion SP3 is not disposed may be prevented from being relatively lowered so that warpage of the second lead frame LF2 is prevented.

According to the semiconductor package CHPK8 according to the embodiment, alignment accuracy of the semiconductor element SCP and the second lead frame LF2 overlapping each other along the height direction DRH may be increased through the second align hole SPH2 and the fourth align hole SPH4 formed at the second protrusion PR2 of the second lead frame LF2, so that misalignment is reduced.

Many features of the example semiconductor packages CHPK1, CHPK2, CHPK3, CHPK4, CHPK5, CHPK6, and CHPK7 according to the embodiments described above are all applicable to the example semiconductor package CHPK8 according to the present embodiment.

Referring to Table 1 below, an experimental example is described.

In the present experimental example, a loss energy of the semiconductor element is measured for a first example according to a typical art where a semiconductor element is mounted on a mounting substrate, the mounting substrate and a lead frame are connected by wire bonding, and the semiconductor element and the lead frame are packaged with a molding portion, and a second example according to the example semiconductor packages of the one or more embodiments where the semiconductor element is mounted between a lower lead frame and an upper lead frame without the complicated process of forming the separate mounting substrate, the plurality of protrusions are formed on a surface of the upper lead frame, and then the semiconductor element, the lower lead frame, the upper lead frame, and the plurality of protrusions are packaged with the molding portion, and the measurement result is shown in Table 1 below.

TABLE 1

| | First | Second | Energy reduction |
|---|---|---|---|
| | Example | Exampler | rate |
| Total loss energy | 11.3 mJ | 9.5 mJ | 15.6% |
| (Eₜₒₜₐₗ) | | | |
| On loss energy (Eₒₙ) | 6.8 mJ | 5.8 mJ | 14.3% |
| Off loss energy (E_{off}) | 4.5 mJ | 3.7 mJ | 18.2% |

Referring to Table 1, it may be seen that the loss energy of the semiconductor element of the second example according to the semiconductor packages of the embodiments is reduced by about 15% or more compared with that of the first example according to the typical art.

While specific examples have been shown and described above, it will be apparent after an understanding of this disclosure that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A semiconductor package, comprising:
a first lead frame and a second lead frame that face each other; and
a semiconductor element that is disposed between the first lead frame and the second lead frame,
wherein the semiconductor element is connected to the first lead frame through a first contacting portion, and is connected to the second lead frame through a second contacting portion, and
wherein the second lead frame comprises a hole that overlaps the second contacting portion.

2. The semiconductor package of claim 1, wherein the second lead frame comprises a plurality of protrusions that protrude toward the semiconductor element.

3. The semiconductor package of claim 2, wherein a cross-section of each of the plurality of protrusions cut in a direction parallel to a height direction has a semicircular shape.

4. The semiconductor package of claim 3, wherein the second lead frame further comprises a first portion and a second portion that are spaced apart from each other, and the plurality of protrusions comprise a first protrusion included in the first portion and a second protrusion included in the second portion.

5. The semiconductor package of claim 4, wherein a width of the first protrusion is substantially equal to a width of the second protrusion.

6. The semiconductor package of claim 5, wherein the hole overlaps the second protrusion.

7. The semiconductor package of claim 2, wherein lower surfaces of the plurality of protrusions are flat.

8. The semiconductor package of claim 7, wherein the second lead frame further comprises a first portion and a second portion that are spaced apart from each other, and the hole comprises a first hole that overlaps a protrusion of the first portion and a second hole that overlaps a protrusion of the second portion.

9. The semiconductor package of claim 8, wherein a width of the protrusion of the first portion is substantially equal to a width of the protrusion of the second portion.

10. The semiconductor package of claim 9, wherein a width of the first hole is substantially equal to a width of the second hole.

11. The semiconductor package of claim 8, wherein a width of the protrusion of the first portion is different from a width of the protrusion of the second portion.

12. The semiconductor package of claim 11, wherein a width of the first hole is different from a width of the second hole.

13. The semiconductor package of claim 1, wherein the first lead frame comprises:
a first frame portion on which the semiconductor element is mounted,
a second frame portion that is spaced apart from the first frame portion, is configured to receive a first signal from an external source, and is disposed in a nonoverlapping manner with regard to the semiconductor element, and
a third frame portion that is spaced apart from the second frame portion, and is disposed in a nonoverlapping manner with regard to the semiconductor element,
wherein the semiconductor package further comprises:
a third contacting portion disposed between the second lead frame and the semiconductor element,
a fourth contacting portion disposed between the second frame portion and the second lead frame and configured to have conductivity, and
a spacer disposed between the third frame portion and the second lead frame.

14. The semiconductor package of claim 13, wherein a thickness of the contacting portion is substantially equal to a thickness of the spacer.

15. A semiconductor package, comprising:
a first lead frame comprising:
a first frame portion on which a semiconductor element is mounted,
a second frame portion that is spaced apart from the first frame portion, is configured to receive a first signal from an external source, and is disposed in a nonoverlapping manner with regard to the semiconductor element, and
a third frame portion that is spaced apart from the second frame portion and is disposed in a nonoverlapping manner with regard to the semiconductor element;
a second lead frame that faces the first lead frame;
a contacting portion that is disposed between the second frame portion and the second lead frame and is configured to have conductivity; and
a spacer disposed between the third frame portion and the second lead frame.

16. The semiconductor package of claim 15, wherein a thickness of the contacting portion is substantially equal to a thickness of the spacer.

17. The semiconductor package of claim 16, wherein the second lead frame comprises a plurality of protrusions that protrude toward the semiconductor element.

18. The semiconductor package of claim 17, wherein a cross-section of each of the plurality of protrusions cut in a direction parallel to a height direction has a semicircular shape.

19. The semiconductor package of claim 17, wherein lower surfaces of the plurality of protrusions are flat.

20. The semiconductor package of claim 19, wherein the second lead frame comprises a first portion and a second portion spaced apart from each other, the plurality of protrusions comprise a first protrusion included in the first portion and a second protrusion included in the second portion, and a width of the first protrusion of the first portion is different from a width of the second protrusion of the second portion.
